(19) United States
(12) Patent Application Publication
(10) Pub. No.: US 2021/0114886 A1
(43) Pub. Date: Apr. 22, 2021

(54) SILICON-CARBON NANOMATERIALS, METHOD OF MAKING SAME, AND USES OF SAME

(71) Applicant: The Research Foundation for The State University of New York, Amherst, NY (US)

(72) Inventors: Parham ROHANI, Lake Bluff, IL (US); Mark SWIHART, Williamsville, NY (US)

(21) Appl. No.: 16/970,266

(22) PCT Filed: Feb. 15, 2019
(86) PCT No.: PCT/US19/18331

§ 371 Date: Aug. 14, 2020

Related U.S. Application Data
(60) Provisional application No. 62/631,039, filed on Feb. 15, 2018.

(51) Int. Cl. C01B 33/113; C01B 32/97; C01B 32/15; H01M 4/134; H01M 4/1395; H01M 4/36; H01M 4/38; H01M 4/62; H01M 10/0525

(52) U.S. Cl. CPC C01B 33/113; C01B 32/97; C01B 32/15; H01M 4/134; B82Y 40/00; H01M 4/366; H01M 4/386; H01M 4/625; H01M 10/0525; H01M 4/1395

(57) ABSTRACT

Described are methods of making silicon-carbon nanocomposite materials. Also provided are silicon-carbon nanocomposite materials, which are made using the methods of the present disclosure. Also provided are electrode materials and ion-conducting batteries including the silicon-carbon nanocomposite materials of the present disclosure.

### CROSS REFERENCE TO RELATED APPLICATIONS

This application claims priority to U.S. Provisional Application No. 62/631,039, filed on Feb. 15, 2018, the disclosure of which is hereby incorporated by reference.

### FIELD OF THE DISCLOSURE

The disclosure generally relates to silicon-carbon nanomaterials. More particularly, the disclosure relates to silicon-carbon nanomaterials for use in electronic technologies.

### BACKGROUND OF THE DISCLOSURE

Over the past 20 years, much research has been conducted to develop and improve rechargeable energy storage technologies with high energy density to support applications such as military and civilian communication devices, electric vehicles, portable electronic devices, and grid-scale and micro-grid-scale energy storage. Among possible energy storage technologies, lithium-ion batteries (LIBs) have attained a dominant position as they have achieved relatively high gravimetric and volumetric energy density, improved safety, and lower manufacturing costs. Further increasing the energy density of LIBs requires adoption of high capacity electrode materials.

Silicon, an environmentally benign element, has been studied extensively as a potential anode material because of its high theoretical capacity (4200 mAh/g), high abundance (28% of the earth's crust by mass), and mature production technologies. Compared to silicon, traditional graphite anodes have significantly lower theoretical capacity (˜375 mAh/g). However, silicon incorporation in LIBs has not been easy. Silicon undergoes massive volume change (up to 400%) upon cycling, accompanied by mechanical stresses, cracking, and side reactions with the electrolyte, which lead to pulverization and continuous formation of an unstable solid electrolyte interface (SEI) layer. Due to these massive volume changes, the SEI breaks and re-forms during each charge/discharge cycle, producing a continuously thickening SEI film that consumes the electrolyte and depletes lithium ions, degrading capacity and ultimately leading to cell failure. To overcome the challenges arising from the massive volume changes of silicon in anodes, researchers have developed micro- and nano-structured silicon-based anode materials. Studies of silicon nanowires as an anode material for LIBs showed that silicon indeed had a promising future in the LIB applications. Further studies focused on pre-lithiation of silicon nanowires, silicon nanowires within hollow graphitic tubes (˜70% silicon content), and SEI layer control in double-walled silicon nanotubes (˜60% silicon content), have demonstrated improvement in battery performance. In another study, graphene sheets were used to disperse silicon nanoparticles (Si NP) between them (˜73% silicon content), which lead to improved capacity. Even though such modifications have improved silicon-based anode performance and increased the specific capacity, they have introduced new challenges such as high surface area for SEI formation, low tap density, and high interparticle electrical resistance that have resulted in low coulombic efficiency and cycling stability or poor rate capability. Furthermore, most of the synthesis processes explored in these studies are not amenable to scale-up.

The demand for high energy density batteries is massive and growing. The LIB market is projected to exceed $77B in 2024. Thus, the market is looking for new materials to increase battery performance. Trying to use silicon as an anode material in LIBs is not new. However, commercially viable combinations of improved performance and large-scale production feasibility have remained elusive. Companies and research institutes have studied silicon-based LIBs for over a decade, but none have reached large market applications such as, for example, cell-phones and electric vehicles. Thus, there exists an ongoing and unmet need for a silicon-based anode material exhibiting desirable performance that not only has high silicon content to achieve high capacity, but is also cost-effective for mainstream applications.

### SUMMARY OF THE DISCLOSURE

The present disclosure provides methods of making silicon-carbon nanocomposite materials. The present disclosure also provides silicon-carbon nanocomposite materials, which can be made by a method of the present disclosure, and electrode materials and ion-conducting batteries including silicon-carbon nanocomposite materials of the present disclosure.

The silicon-carbon nanomaterials and methods of the present disclosure are related to the problems associated with silicon materials of the prior art. The silicon-carbon nanomaterials and methods of the present disclosure can combine the performance of high silicon content anode materials with capacity retention and large-scale production feasibility.

In an aspect, the present disclosure provides methods of making silicon-carbon nanomaterials. In various examples, methods of the present disclosure are described herein. As an illustrative example, carbon coated silicon oxide coated silicon nanoparticles are referred to as silicon@oxide@carbon. The method may be a “one pot” method.

In an aspect, the present disclosure provides silicon-carbon nanomaterials. In various examples, the silicon-carbon nanomaterials are made by a method of the present disclosure. In various examples, silicon-carbon nanomaterials of the present disclosure are described herein.

In an aspect, the present disclosure provides anode materials. The anode materials comprise one or more silicon-carbon nanomaterials of the present disclosure. In various examples, anode materials of the present disclosure are described herein.

The active silicon-carbon nanomaterials can be used to fabricate anode electrodes by, for example, mixing the active material with additives as described herein (e.g., carbon nanotubes or carbon black or graphene sheets) and binders as described herein (e.g., PVDF, PAA, CMC, Alginate, and combinations thereof) with a mass ratio of, for example, 65:20:15. The mass ratio can be changed. Anode fabrication proceeds by standard processes used with any powdered anode material. In an example, an anode electrode comprises a silicon-carbon nanomaterial and does not comprise a binder (e.g., an aqueous binder). In various examples, the acid etch (e.g., using an aqueous solution of HF or gaseous HF) is carried out before or after electrode formation.

In an aspect, the present disclosure provides ion-conducting batteries. The ion-conducting batteries comprise one or more one or more silicon-carbon nanomaterials of the present disclosure and/or one or more anode materials of the present disclosure. The batteries may be rechargeable batteries. The batteries can be lithium-ion batteries. In various examples, anode materials of the present disclosure are described herein.

### BRIEF DESCRIPTION OF THE FIGURES

For a fuller understanding of the nature and objects of the disclosure, reference should be made to the following detailed description taken in conjunction with the accompanying figures.

FIG. 1 shows A) synthesis mechanism of silicon-carbon structure with the required void space. B) Effect of lithiation and delithiation process on the silicon-carbon structure. C) Increase in tap density and decrease in surface accessible to the electrolyte (SEI formation) by clustering the loose silicon-carbon aggregates.

FIG. 2 shows A-C) scanning electron microscopy (SEM) images of the silicon-carbon anode material at different magnifications. D-E) Transmission electron microscope (TEM) images of the silicon-carbon structures, without cluster formation. F) TEM image of the carbon shell. G) TEM image of the silicon-carbon particles after pressing at 950 MPa to test the integrity of the carbon shell.

FIG. 3 shows transmission Electron Microscope images. A) A silicon nanoparticle at high magnification. B) Silicon nanoparticles at low magnification. C) Silicon-carbon nanocomposite with small void space. D) Silicon-carbon nanocomposite with large void space. E-F) Silicon-carbon composite using 100 nm silicon particles.

FIG. 4 shows characterization of the silicon-carbon nanocomposite. A) X-ray diffraction. B) Raman spectrum. C) Thermogravimetric analysis using air as a carrier gas.

FIG. 5 shows results of galvanostatic cycling of silicon-carbon nanocomposite A) without void space or B) with void space. All samples were cycled at C/50 for the first cycle, C/20 for the second cycle, and C/10 for the later cycles (1C=4200 mAh/g). Solid circles: 35 nm particles. Empty Circles: 100 nm particles.

FIG. 6 shows results of galvanostatic cycling of the 35 nm silicon-carbon nanocomposite with void space. The half-cell was cycled at C/10 for the first cycle, C/3 for the second cycle, and C/1.2 (0.62 mA/cm²) for the later cycles (1C=4200 mAh/g).

FIG. 7 shows SEM images of a working electrode comprised of the silicon-carbon anode material and CNT as conductive carbon additive. A-C) Low and high magnification images of electrodes produced with a fast-drying process, showing the cracks and CNTs bridging them. D) Low magnification image of the slowly-dried film showing no crack formation.

FIG. 8 shows results of galvanostatic cycling of the silicon-carbon anode material at different current densities. The current density for sections A to F are 0.023, 0.056, 0.113, 0.226, and 0.564 mA/cm², respectively.

### DETAILED DESCRIPTION OF THE DISCLOSURE

Although subject matter of the present disclosed is described in terms of certain embodiments and examples, other embodiments and examples, including embodiments and examples that do not provide all of the benefits and features set forth herein, are also within the scope of this disclosure. Various structural, logical, and process step changes may be made without departing from the scope of the disclosure.

Ranges of values are disclosed herein. The ranges set out a lower limit value and an upper limit value. Unless otherwise stated, the ranges include all values to the magnitude of the smallest value (either lower limit value or upper limit value) and ranges between the values of the stated range.

The present disclosure provides methods of making silicon-carbon nanocomposite materials. The present disclosure also provides silicon-carbon nanocomposite materials, which can be made by a method of the present disclosure, and electrode materials and ion-conducting batteries including silicon-carbon nanocomposite materials of the present disclosure.

The silicon-carbon nanomaterials and methods of the present disclosure are related to the problems associated with silicon materials of the prior art. The silicon-carbon nanomaterials and methods of the present disclosure can combine the performance of high silicon content anode materials with capacity retention and large-scale production feasibility.

For example, the present disclosure describes a cost-effective silicon-based anode material with more than 80% silicon content and high gravimetric and volumetric capacity. The present disclosure, in various examples, describes silicon-carbon micron-sized clusters containing silicon nanoparticles coated with graphene-like carbon.

In an aspect, the present disclosure provides methods of making silicon-carbon nanomaterials. In various examples, methods of the present disclosure are described herein. As an illustrative example, carbon coated silicon oxide coated silicon nanoparticles are referred to as silicon@oxide@carbon. The method may be a “one pot” method.

In an example, the method comprises:
a) Forming silicon oxide (e.g., silica) coated silicon nanoparticles by oxidizing silicon nanoparticles (e.g., silicon nanoparticles with characteristic dimensions of 100 to 250 nanometers) in a furnace (e.g., a furnace that is heated to 700° C. at a rate of 5° C./min under air, and held at 700° C. for 6 hours). The materials may be actively mixed during oxidation.
b) Carbon coating (e.g., carbon coating by chemical vapor deposition) the silica-coated silicon nanoparticles in a furnace (e.g., in a furnace heated to 900° C. using a gas (e.g., acetylene gas)). The materials may be actively mixed during this process.
c) Mechanically pressing the carbon and silica-coated silicon (e.g., pressed to a pressure of up to 100 MPa).
d) Sintering the pressed pellets in an oxygen-free furnace (e.g., an oxygen-free furnace at 500° C. for at least 2 hours).
e) Milling the sintered pellets to produce micron-sized clusters with 10 μm average size.
f) Optionally, carbon coating the clusters for a second time by repeating step b).
g) Etching the clusters (e.g., etching in an HF solution) to dissolve the silica layer, where the final product is formed.
   The final product is, for example, a micron-sized silicon-carbon composite active material that can be used to create an anode electrode.

In an example, a method does not comprise a solution phase process. In another example, a method does not comprise a solution phase deposition process.

In various examples, silicon oxide-coated silicon nanoparticles are used. The silicon oxide layer can be referred to as a sacrificial layer. The silicon oxide can be a stoichiometric oxide or a sub-oxide. For example, the silicon oxide is SiOₓ, where x is 1-2, including all 0.1 values and ranges therebetween.

In an example, silicon oxide-coated silicon nanoparticles are formed by growing a silica (silicon oxide) shell by deposition onto silicon nanoparticles, which can be obtained the commercially, (e.g., ˜100 nm silicon nanoparticles). In another example, silicon nanoparticles are thermally oxidized to leave a smaller core and a sacrificial oxide shell. As shown in FIG. 1 in Example 1, this can produce a material very similar to that obtained starting from smaller ˜35 nm particles, but using low-cost starting material and low-cost processing steps.

In an example, the synthesis process: thermal oxidation of silicon particles; carbon coating; cluster formation by pressing and milling; carbon coating; and acid etching. In an example, the first carbon coating is optional. In another example, the second carbon coating is optional.

A thermal oxidation may provide silicon nanoparticles with a porous silicon oxide coating. These pores may provide paths from the nanoparticle exterior to the silicon core.

The silicon oxide coated nanoparticle may be formed from a single silicon nanoparticle, a cluster of a plurality of nanoparticles, a plurality of partially agglomerated nanoparticles, or a combination thereof. All of these nanoparticles are referred to as silicon-oxide coated nanoparticles. A silicon nanoparticle may spherical or non-spherical.

In an example, commercially-available silicon particles (e.g., >100 nm) are thermally oxidized up to the desired thickness to form silica coated silicon particles. With this approach, we not only grow a silica layer on the surface, but also controllably decrease the size of the final silicon particle to the nano-scale (e.g., <75 nm). This is advantageous because smaller particles can perform better than larger particles due to shorter lithium ion diffusion distance within them and greater resistance to volume-change-induced degradation. Thermal oxidation of silicon is a well-known process that can be carried out in a furnace in air, with or without water or oxygen addition, at any scale, with or without active mixing. The silica coating thickness can be tuned by, for example, changing the oxidation time and temperature. This tuning provides a means to optimize the void space and silicon core size. Then, the product is pressed using, for example, a die set and hydraulic press or by a continuous roll press to pack the individual oxidized silicon particles. Then, the pressed particles may be sintered, e.g., in the same furnace used for oxidation, which can prevent the pressed particles from breaking into individual (free) nanoparticles during the milling process. Then, the sintered product is milled using, for example, a planetary ball mill and zirconia/steel balls, to form clusters of oxidized silicon particles. The cluster size can be tuned, for example, by simply changing the mill type, milling time, milling speed, and ball size. Then, the same furnace may be used for the carbon chemical vapor deposition (CVD) process. In this case, rather than air, acetylene gas or a similar hydrocarbon is used, with or without nitrogen, hydrogen, and/or argon dilution for a few seconds to minutes at reduced (sub-atmospheric) pressure. The carbon thickness can be tuned, for example, by changing the process time and gas flow rate. The carbon type depends on the temperature. Carbon coating can provide various forms of carbon. For example, the carbon coating is an amorphous, polycrystalline, or single crystalline carbon coating and/or the carbon coating comprises graphitic carbon. In an example, the carbon coating is not 95%, 98%, 99%, or 100% amorphous and/or is not 95%, 98%, 99%, or 100% graphene and/or graphitic carbon. Carbon coating may produce multi-domained carbon (e.g., a plurality of carbon domains, where the individual carbon domains are amorphous, polycrystalline, or single crystalline.

In an example, the carbon coating is carried out at a temperature of less than or equal to 1100° C. (e.g., less than or equal to 800° C.). Without intending to be bound by any particular theory, it is considered that carbon coating provided by a CVD process carried out at a temperature of less than or equal to 800° C. provides exhibits a desirable level of conformity.

Carbon coating may be carried out using a CVD process with only one or more carbon precursor. In an example, carbon coating is carried out using a CVD process that includes a gas (e.g., nitrogen gas, hydrogen gas, or the like, or a combination thereof) that leads to doping of the carbon coating (e.g., with nitrogen). Without intending to be bound by any particular theory it is considered that silicon-carbon nanomaterials formed by one of these processes can be used to form an anode with an aqueous binder.

It is desirable to avoid forming 100% amorphous or 100% graphitic carbon. Amorphous carbon is highly porous and irreversibly traps lithium ions. On the other hand, the presence of some pores in the carbon shell is desired for transport of lithium-ions across the carbon layer. Therefore, it is desirable to use of a temperature that is high enough to produce graphene-like or graphitic material, but not high enough to form high-quality (defect-free) graphene or graphite. Increased graphene/graphitic carbon content increases the electrical conductivity and improves the coulombic efficiency by trapping fewer lithium ions. The acetylene gas or other hydrocarbon decomposes in the tube furnace, goes through the pores and coats the individual oxidized silicon particles. Graphene formation on the oxidized silicon is more prevalent than amorphous carbon deposition, because the oxide produces catalytic sites that facilitate graphitization. In various examples, the carbon coating process can be done either before or after the cluster formation process, or both before and after.

Silicon oxide coated silicon nanoparticles can be formed (e.g., as described herein) from silicon nanoparticles having various sizes (e.g., size is the longest dimension of the nanoparticle). In various examples, the starting silicon nanoparticles are less than 100 nm, less than 125 nm, less than 150 nm, less than 175 nm, less than 200 nm, or less than or equal to 250 nm in size. In various examples, the starting silicon nanoparticles are less than 100 nm, less than 125 nm, less than 150 nm, less than 175 nm, less than 200 nm in size, or less than or equal to 250 nm in size and the silicon core of the silica coated silicon nanoparticle has a size of less than 50 nm, less than 100 nm, less than 150 nm, less than 200 nm. In an example, the silicon oxide coated silicon nanoparticles are not formed using a Stöber synthesis. In an example, the silicon oxide coated silicon nanoparticles are formed without a separation (e.g., isolation) step. In an example, the silicon oxide coated silicon nanoparticles are formed without a liquid separation (e.g., isolation) step.

Carbon coating can be carried out at various times. Carbon coating may be carried out before cluster formation. For example, the silicon oxide-coated silicon nanoparticles are carbon coated. Carbon coating may be carried out after cluster formation. For example, the silicon oxide-coated silicon nanoparticle clusters are carbon coated. Carbon coating may be carried out before cluster formation and after cluster formation. For example, the silicon oxide-coated silicon nanoparticles are carbon coated and the silicon oxide-coated silicon nanoparticle clusters are carbon coated. The carbon coating may provide a nanoparticle comprising a silicon core and a composite silicon oxide-carbon shell disposed on at least a portion or all of the silicon core.

Without intending to be bound by any particular theory, it is considered that carbon coating before cluster formation reduces the amount of carbon additive, if used, necessary to achieve a given electrical conductivity of the electrode. For example, a silicon-carbon nanocomposite is carbon coated before silicon oxide-coated silicon nanoparticle cluster formation and the silicon-carbon nanocomposite does not comprise addition of conductive carbon additive(s) during electrode fabrication.

After carbon coating, acid etching is used, for example, to remove the oxide layer and provide the void space necessary for silicon volume expansion. Acid etching may be carried out using gaseous hydrogen fluoride or a hydrogen fluoride solution. For example, after filtering, washing and drying, the silicon-carbon clusters are ready to use. The acid etching process is easily scalable. In various examples, the hydrofluoric acid concentration for etching is as low as 5% and the process time as low as half an hour.

It is believed the methods described herein are scalable. For example, at a 10 g scale, uniformity in the thermal oxidation and carbon coating process is not an issue. However, at larger scales, use of an actively mixed device as such a rotary furnace may assist in formation of uniform oxide and carbon layers. A laboratory rotary furnace is functionally equivalent to rotary kilns that can be operated continuously and at tonnage scales. Pressing and milling equipment routinely operates at similar scales.

In an example, the silicon-carbon nanocomposite comprises a silicon nanoparticle (e.g., a silicon core) having a longest dimension (e.g., diameter) of less than or equal to 50 nm, less than or equal to 100 nm, less than or equal to 150 nm, or less than or equal to 200 nm, where the silicon nanoparticle is surrounded by a void space and a carbon coating (e.g., a carbon shell). The silicon nanoparticle (e.g., silicon core) may be crystalline, polycrystalline, amorphous, or a combination thereof.

The crystallinity of the silicon in the final product can be examined by, for example, X-ray diffraction (XRD). For example, thermogravimetric analysis (TGA) of the final product using air as a carrier gas can be used to measure the carbon content. Fundamentally, oxygen in the air oxidizes the carbon, forms carbon dioxide and leaves the sample. The weight loss measured by the system shows the carbon content. Furthermore, Raman spectroscopy analysis can be used to analyze the carbon type in the sample. Amorphous carbon can readily be distinguished from graphene using this technique. XRD is another technique that is used to characterize carbon. However, because the (111) silicon peak is very close to the characteristic peak of graphene, carbon characterization in our samples by XRD is not straightforward. To do so, silicon nanoparticles in the sample are removed by sodium hydroxide etching. After washing and drying, the product is 100% carbon and can be characterized by XRD. BET surface area measurement will determine surface area and porosity of the final product. This data can be used to optimize the milling process to optimize the cluster size.

In various examples, a method of the present disclosure comprises:
Providing or forming Si NP (e.g. of approximately 100 nm diameter)
Thermal oxidation (e.g., using a tube furnace in air), which results in growth of a silicon oxide layer reduction of the size of the Si NP core (e.g. to <75 nm diameter)
Pressing (e.g. using a hydraulic press) to form clusters
Sintering to stabilize clusters
Milling (e.g., ball milling) to reduce the size of clusters (e.g., to ˜1-15 microns)
CVD carbon coating (e.g., using acetylene, for example, in a tube furnace)
Acid etching to remove sacrificial silicon oxide layer (e.g., in a large plastic vessel)

In an example, a method of the present disclosure comprises:
Providing or forming Si NP (e.g., of approximately 100 nm diameter)
CVD carbon coating (e.g., using acetylene)
Pressing (e.g. using a hydraulic press) to form clusters
Sintering
Milling (e.g., ball milling) to reduce the size of clusters (e.g., to ˜1-15 microns)
Acid etching to remove sacrificial silicon oxide layer (e.g., in a large plastic vessel)

In an example, a method of the present disclosure comprises:
de novo synthesis of Si NPs (e.g., by laser pyrolysis (of silane or dichlorosilane) to produce Si NPs)
Growth of a sacrificial silicon oxide layer from another silicon source (e.g., using TEOS)
Filter/centrifuge→wash dry
Press (e.g. using a hydraulic press) to form clusters
Sinter
Mill (e.g., ball mill) to reduce size of cluster (e.g., to ˜1-15 microns)
CVD carbon coat (e.g., acetylene, for example, in same tube furnace)
Acid etch to remove sacrificial silicon oxide layer (e.g., in a large plastic vessel)

In an example, silicon nanoparticle synthesis is by wet/dry milling of metallurgical-grade silicon (or silicon wafer waste from solar/semiconductor industry), followed by the rest of the steps. The size of the silicon nanoparticles ranges from 50 to 300 nm, including every 0.1 nm value and range therebetween.

In an example, because of the cold-welding phenomena during the milling process, the silicon nanoparticles aggregate and form micron-sized aggregates. In such an example, the cluster formation step is omitted.

In an example, an oxidizer (e.g., nitric acid and the like) is added to the milling jar to oxidize the particles and form the sacrificial layer.

In another example, a sacrificial oxide layer can be created by an oxidizer (e.g., nitric acid and the like) either in the milling process or afterward in a separate step.

In another example, another possible way to create the sacrificial layer is to coat the silicon nanoparticles with sulfur. The sulfur layer can be evaporated at moderate temperatures to create the void space.

The silicon oxide layer can be removed by, for example, acid etch using aqueous HF (e.g., ˜45% by weight aqueous solution) or gaseous HF. For example, the particles are dispersed in ethanol. Then, the HF is added to keep the amount of water low.

The following are three examples of methods of the present disclosure that can produce nano-sized particles of the present disclosure:

1) Silicon nanoparticles are synthesized in a laser pyrolysis reactor using silane as a precursor. The nanoparticles are 25-35 nm in size. However, any similar nano-scale silicon can be used. The synthesized nanoparticles are hydrogen passivated, which hinders fast oxidation of the nanomaterial. The particles are heat treated at 700° C. (other temperatures in the range 400° C. to 1100° C. (e.g., 400° C. to 1000° C.), including all 0.1° C. values and ranges therebetween, are also effective) under argon (or vacuum or other inert environment) for an hour (or other appropriate time based on temperature used) to replace the surface hydrogen bonds with hydroxide bonds. This helps to grow a uniform silica layer on the surface. A silica sacrificial layer is grown on the silicon surface in a basic aqueous solution using TEOS with 24 hours stirring time. Silica layer size is tunable by changing the TEOS concentration, pH and stirring time. Then, the silica-coated silicon particles are separated from the solution by filtration or centrifugation and washed with water. The particles dry overnight. Then the particles are pressed using a hydraulic press to pack the particles and decrease the tap density. The pellets are sintered at 600° C. for two hours under argon (or vacuum or other inert environment). Sintering time and temperature can be varied to optimize the degree of sintering. Then micron-size clusters are formed by ball milling the pellets. The cluster sizes are tunable by changing the milling time, speed, number of balls and other parameters. Then, the particles are carbon coated by chemical vapor deposition (CVD) using acetylene at 1100° C. for one minute with 200 sccm gas flow rate. The carbon thickness is tunable by changing the gas flow rate and time. Other temperatures in the range from 700° C. to 1500° C. (e.g., 800° C. to 1500° C.), including all 0.1° C. values and ranges therebetween, are also effective in combination with appropriate coating times and gas flow rates. Then, the silica sacrificial layer is removed by hydrofluoric acid (HF) etching. The maximum HF concentration needed is 10% w/w and the maximum etching time could be an hour. Of course, lower HF concentration requires longer etching time. Then, the particles are separated from the solution, washed with ethanol and dried overnight.
2) The surface of commercially available silicon particles (e.g., ˜100 nm silicon particles) are thermally oxidized at 700° C. (5° C./min heating rate) in the air for four hours to provide the sacrificial silicon oxide layer. Other temperatures from 500° C. to 1000° C. (e.g., 600° C. to 1000° C.), including all 0.1° C. values and ranges therebetween, and other heating rates can also be used with appropriate adjustments of the heating time. For example, other oxidizing mixtures containing water vapor, nitrous oxide, or oxygen concentrations different from ambient air can also be used. The silicon oxide layer thickness is tunable by changing the furnace temperature, heating rate, isothermal reaction time and gas composition (oxygen and moisture content). Then, the particles are pressed using a hydraulic press to pack the particles and decrease the tap density. The pellets are sintered at 600° C. for two hours under argon (or vacuum or another inert atmosphere). Other temperatures from 500° C. to 800° C., including all 0.1° C. values and ranges therebetween, can also be used with appropriate adjustment of the sintering time. Then, micron-size clusters are formed by ball milling the pellets. The cluster sizes are tunable by changing the milling time, speed and number of balls. Then, the particles are carbon-coated by chemical vapor deposition (CVD) of acetylene at 1100° C. for one minute with 200 sccm gas flow rate (e.g., at the specific scale of this example). The carbon thickness is tunable by changing the gas flow rate and time. Other temperatures in the range from 700° C. to 1500° C. (e.g., 800° C. to 1500° C.), including all 0.1° C. values and ranges therebetween, are also effective in combination with appropriate coating times and gas flow rates. Then, the silica sacrificial layer is removed by HF etching. The maximum HF concentration needed is 10% w/w and the maximum etching time could be an hour. Of course, lower HF concentration requires longer etching time. Then, the particles are separated from the solution, washed with ethanol, and dried overnight.
3) Commercially available (e.g., ˜100 nm silicon particles) are carbon coated by chemical vapor deposition (CVD) of acetylene at 1100° C. for one minute with 200 sccm gas flow rate (e.g., at the particular scale of this example). The carbon thickness is tunable by changing the gas flow rate and time. Other temperatures in the range from 700° C. to 1500° C. (e.g., 800° C. to 1500° C.), including all 0.1° C. values and ranges therebetween, are also effective in combination with appropriate coating times and gas flow rates. Then, the particles are pressed using a hydraulic press to pack the particles and decrease the tap density. The pellets are sintered at 600° C. for two hours under argon (or vacuum or another inert atmosphere). Other temperatures from 500° C. to 800° C., including all 0.1° C. values and ranges therebetween, can also be used with appropriate adjustment of the sintering time. Micron-size clusters are formed by ball milling the pellets. The cluster sizes are tunable by changing the milling time, speed and number of balls. Then, a 1 molar lithium hydroxide solution is used to etch the silicon inside the carbon shells for an hour at 70° C. under constant stirring in order to provide the required void space. Other lithium hydroxide solution concentrations can be employed, with appropriate changes in the etching time. The void space is tunable by changing the concentration, temperature and stirring time. The silicon etching process can be performed using sodium hydroxide and/or potassium hydroxide solutions in place of lithium hydroxide as well, or can use mixtures of these or similar agents. Synthesizing a uniform void space by this method is more challenging than through oxidation because the etching solution has to penetrate into the clusters to reach all the silicon particles, and the etching is anisotropic (proceeding faster in some crystallographic directions than others).
Variations of each of these approaches are possible, including multiple carbon deposition steps, before and after pressing, sintering, and milling, to improve the electrical conductivity of the composite anode material. However, increased carbon content decreases the overall lithium storage capacity (by decreasing the silicon content) and carbon can also irreversibly trap lithium ions. Thus, it desirable to optimize the carbon coating steps.

A method of the present disclosure can exhibit one or more of the following characteristics:
Increase Si content (e.g., to 90%)
The nanomaterials can endure significant stress w/o cracking
25-35 nm, oxide-free, hydrogen-passivated silicon nanoparticle core
Void space (tunable) allows for expansion and contraction w/o disruption or cracking shell
Formed following acid etching of sacrificial silica layer
Carbon shell protects active material from electrolyte and allows for electronic and ionic conduction
Tunable by altering CVD time
Short electronic and ionic transport distances provide improved rate capability
Can form clusters to reduce exposure to electrolyte (less surface area) while also decreasing carbon content
Higher surface area of Si NP can induce more SEI layer formation, which consumes more Li ions
Formation of clusters prior to acid etching decreases surface area for SEI formation by limiting SEI formation to the exterior of each cluster rather than each encapsulated Si nanoparticle
Tunable cluster size (e.g., via ball milling time)

In an aspect, the present disclosure provides silicon-carbon nanomaterials. In various examples, the silicon-carbon nanomaterials are made by a method of the present disclosure. In various examples, silicon-carbon nanomaterials of the present disclosure are described herein.

In various examples, the silicon-carbon materials of the present disclosure have silicon nanoparticles encapsulated in a carbon shell. Graphene-like or graphitic carbon encapsulation of each silicon nanoparticle is also advantageous because such carbon has higher conductivity and lower porosity compared to amorphous carbon. Therefore, fewer lithium ions are trapped within the carbon, which leads to higher coulombic efficiency.

Nano-sized particles can accommodate significant stress without cracking, while providing short electronic and ionic transport distances that improve rate capability. The encapsulation with empty space allows room for the silicon to expand and contract without disrupting anode microstructure or breaking the carbon shell. The carbon layer protects the electrode material from the continual exposure to the electrolyte. The carbon shell is also electronically and ionically conducting, which allows for desirable lithiation/delithiation kinetics.

The nano-sized particles of the present disclosure can accommodate significant stress without cracking while providing short electronic and ionic transport distances that improve charge/discharge rate capability. The void space allows room for the silicon to expand and contract without disrupting the anode microstructure or breaking the carbon shell.

Without intending to be bound by any particular theory, it is considered that silicon-carbon materials of the present disclosure, which, in various examples, comprise silicon nanoparticles encapsulated in a carbon shell with a void space, address one or more of the problems associated with silicon materials used as anodes for lithium-ion batteries (e.g., size expansion of silicon upon lithium incorporation and SEI layer formation). It is also considered that cluster formation reduces the surface area accessible to the electrolyte, leading to higher initial cycle coulombic efficiency (less SEI formation) and longer cycle life while decreasing the total carbon content. It is also considered that surface area reduction by cluster formation decreases the overall SEI layer formation and ultimately decreases lithium-ion consumption by irreversible reactions.

In an aspect, the present disclosure provides anode materials. The anode materials comprise one or more silicon-carbon nanomaterials of the present disclosure. In various examples, anode materials of the present disclosure are described herein.

The active silicon-carbon nanomaterials can be used to fabricate anode electrodes by, for example, mixing the active material with additives as described herein (e.g., carbon nanotubes or carbon black or graphene sheets) and binders as described herein (e.g., PVDF, PAA, CMC, Alginate, and combinations thereof) with a mass ratio of, for example, 65:20:15. The mass ratio can be changed. Anode fabrication proceeds by standard processes used with any powdered anode material. In an example, an anode electrode comprises a silicon-carbon nanomaterial and does not comprise a binder (e.g., an aqueous binder). In various examples, the acid etch (e.g., using an aqueous solution of HF or gaseous HF) is carried out before or after electrode formation.

The electrode can have various thicknesses. In an example, an electrode has a thickness of about 100 nm.

The electrode can be formed using various processes. In an example, an electrode is formed using roll processing.

The electrode may comprise one or more silicon-carbon nanomaterials of the present disclosure. The electrode may also comprise a binder, a carbon additive, a metal current collector (e.g., copper), or a combination thereof. In an example, an electrode does not comprise a polymer coating.

In an example, adding the conductive carbon additives is excluded if the active material has enough carbon. For example, the mass ratio becomes 85:0:15. Without being bound by any particular theory, it is considered the first carbon coating step creates the carbon shell for each silicon particle. The second carbon coating step (of clusters) not only fills all the pores in the cluster but may also create a carbon shell around the cluster. Also, the conductivity would be higher. Therefore, it is expected the conductive additive may be avoided.

In an example, electrodes are fabricated on a thin copper foil (current collector) using a slurry method. The slurry was prepared by mixing the active material (silicon-carbon cluster), conductive carbon material, and binder, for example, in ratios of 65:20:15. This ratio can be varied. The current collector can have mesh morphology rather than being flat. After applying the anode material on the current collector, the anode material is dried (e.g., overnight at 100-120° C.). After cooling down the furnace, the film is roll-pressed to decrease the thickness and pack the material. Then, a pre-lithiation process may be carried out. Pre-lithiation process can be carried out, for example, by connecting the electrode and lithium metal foil across a variable resistor. The resistor enables monitoring of the voltage and current to control the rate of the pre-lithiation process. A desirable pre-lithiation ends at a point where the final potential is below that at which the solid electrolyte interface (SEI) layer forms, thus circumventing electrolyte decomposition during the initial cycle, but above that of the main alloying reaction. The pre-lithiation open circuit voltage (after several hours of relaxation) should be slightly below ˜0.34V, which corresponds to Li—Si alloy formation (Li_{0→1.71}Si).

In another example, the electrodes can be prepared through physical vapor deposition.

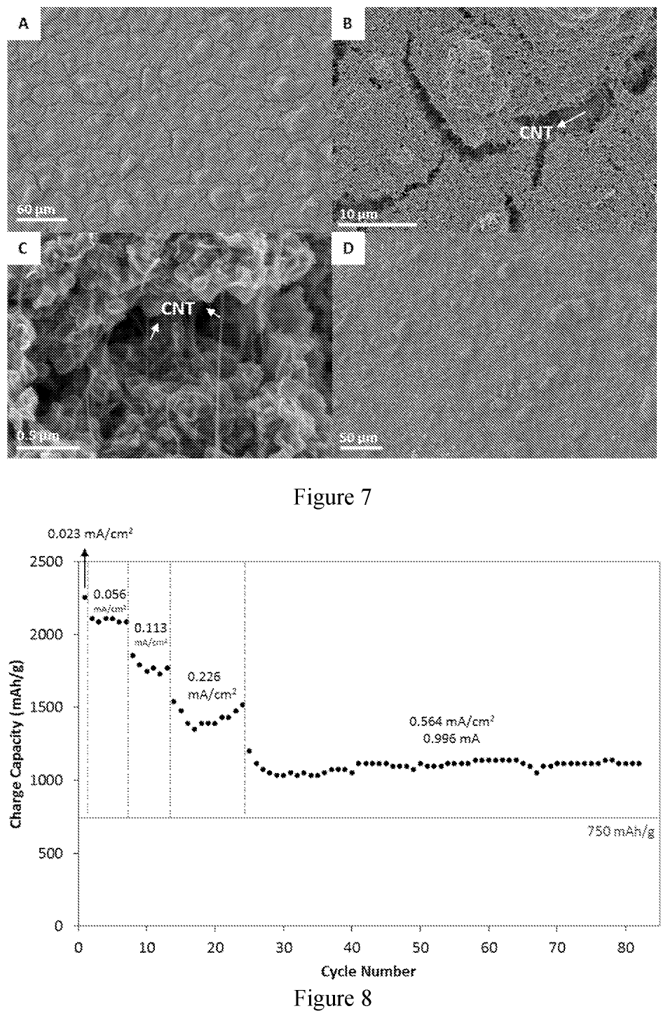

It may be desirable to use carbon nanotubes (CNT) because during the drying process, the slurry may form surface cracks. Carbon nanotubes bridge these cracks, maintaining good electrical contact across the cracks and preventing capacity loss due to electrically isolated material (FIGS. 7. A-C). The crack formation can be avoided by drying the electrode more slowly (FIG. 7. D).

In an example, 15 mm diameter electrodes are punched and weighed to measure the amount of the active material in each electrode. Coin cells are fabricated in an argon-filled glovebox using the working electrode and a lithium metal foil counter/reference electrode. The oxygen and moisture concentrations in the glovebox are maintained below 1 ppm.

Clusters (e.g., clusters of individual silicon oxide-coated silicon nanoparticles and individual carbon-material-coated silicon nanoparticles) can be formed during fabrication of an anode or anode material. High pressures (e.g., pressures used to form clusters as described herein and pressures used to fabricate anodes) do not break the carbon shells. Accordingly, in any method disclosed herein the cluster formation can be omitted from the method and the clusters of individual particles (e.g., individual silicon oxide-coated silicon nanoparticles and individual carbon-material-coated silicon nanoparticles) can be formed during fabrication of an anode (e.g., the electrode is pressed at the same pressure used to perform the cluster formation).

In an aspect, the present disclosure provides ion-conducting batteries. The ion-conducting batteries comprise one or more one or more silicon-carbon nanomaterials of the present disclosure and/or one or more anode materials of the present disclosure. The batteries may be rechargeable batteries. The batteries can be lithium-ion batteries. In various examples, anode materials of the present disclosure are described herein.

The ion-conducting batteries can comprise one or more cathode. Various cathodes/cathode materials are known in the art.

The ion-conducting batteries can comprise one or more electrolyte. Various electrolyte materials are known in the art.

The ion-conducting batteries can comprise current collector(s). For example, the current collectors are each independently fabricated of a metal (e.g., aluminum, copper, or titanium) or metal alloy (aluminum alloy, copper alloy, or titanium alloy).

The ion-conducting batteries may comprise various additional structural components (e.g., bipolar plates, external packaging, and electrical contacts/leads to connect wires). In an example, the battery further comprises bipolar plates. In an example, the battery further comprises bipolar plates and external packaging, and electrical contacts/leads to connect wires.

The cathode(s), anode(s) (if present), electrolyte(s) (if present), and current collector(s) (if present) may form a cell. In this case, the ion-conducing battery comprises a plurality of cells separated by one or more bipolar plates. The number of cells in the battery is determined by the performance requirements (e.g., voltage output) of the battery and is limited only by fabrication constraints. For example, the battery comprises 1 to 500 cells, including all integer number of cells and ranges therebetween.

In an example, the ion-conduction battery or ion-conducting battery cell has one planar cathode and/or anode-electrolyte interface or no planar cathode and/or anode-electrolyte interfaces.

Ion-conducting batteries can comprise one or more electrochemical cells, such cells generally comprising a cathode, an anode and an electrolyte. Provided that they comprise one or more anode of the present disclosure, in various examples, the battery comprises any suitable component part (e.g., anode, electrolyte, separator, etc.). It is within the discretion of a person having ordinary skill in the art to readily select such components.

The batteries can have various uses. For example, the batteries are used in consumer applications and automotive and other large scale applications.

The steps of the methods described in the various embodiments and examples disclosed herein are sufficient to carry out the methods of the present disclosure. Thus, in an example, a method consists essentially of a combination of the steps of the methods disclosed herein. In another example, a method consists of such steps.

The following Statements describe examples of silicon-carbon nanomaterials of the present disclosure and methods of making and using silicon-carbon nanomaterials of the present disclosure:

Statement 1. A method for making a silicon-carbon nanocomposite material (e.g., a silicon-carbon nanocomposite material comprising a plurality of silicon@void@carbon clusters) comprising: providing silicon oxide (e.g., silicon dioxide)-coated nanoparticles (e.g., silicon nanoparticles with a continuous coating of silicon oxide) (e.g., forming silicon oxide (e.g., silicon dioxide)-coated nanoparticles by heating (e.g., thermally oxidizing) silicon nanoparticles in an oxidizing atmosphere (e.g., air, water, oxidizing gases such as, for example, ozone, nitrous oxides, and the like), sol-gel methods, such as, for example, Stöber methods, and the like) having, for example, a silicon oxide thickness of 5 to 500 nm, including all nm ranges and values therebetween (e.g., 1-300, less than 250 nm, or less than 150 nm); forming clusters of silicon oxide-coated silicon nanoparticles (e.g., by applying pressure to the silicon oxide-coated silicon nanoparticles (e.g., using a die set and hydraulic press, a tablet press, a stamp press, or a roller press, and the like) to form compacted (e.g., agglomerated) clusters of silicon oxide-coated silicon nanoparticles and milling (e.g., ball milling, hammer milling, jet milling, roller milling, and the like) the compacted clusters of silicon oxide-coated silicon nanoparticles to form clusters of silicon oxide-coated silicon nanoparticles of desired size (e.g., 1 to 50 microns, including all micron values and ranges therebetween); forming carbon-material (e.g., carbon material such as, for example, graphene, graphene-like material, graphitic carbon material, amorphous carbon, or a combination thereof)-coated clusters of silicon oxide-coated silicon nanoparticles (e.g., by contacting the clusters of silicon oxide-coated silicon nanoparticles with a gas-phase carbon precursor such as, for example, acetylene, ethylene, methane, ethanol, acetone, or a combination thereof and, optionally, a reducing gas, such as, for example, hydrogen, nitrogen, and ammonia) having, for example, a carbon material thickness of 0.3 to 20 nm, including all 0.1 nm values and ranges therebetween (e.g., 0.3-5 nm and 5-10 nm); and removing all or substantially all (e.g., 80% or greater, 85% or greater, 90% or greater, and 95%, or greater) of the silicon oxide from the carbon-material-coated clusters of silicon oxide-coated silicon nanoparticles (e.g., by contacting the carbon-coated clusters of silicon oxide-coated silicon nanoparticles with an acid such as, for example, aqueous hydrofluoric acid, a base, such as, for example, a Group I metal hydroxide, or a fused hydroxide), such that the silicon-carbon nanocomposite material is formed.
Statement 2. A method for making a silicon-carbon nanocomposite material (e.g., a silicon-carbon nanocomposite material comprising a plurality of silicon@void@carbon clusters) comprising thermal oxidation of silicon particles; carbon coating; cluster formation by pressing and milling; second carbon coating; and acid etching.
Statement 3. A method according to any one of the preceding Statements, wherein there are at least two carbon coating steps and the carbon coating steps are done before or after the cluster formation process, or both before and after.
Statement 4. A method according to any one of the preceding Statements, further comprising isolating the silicon-carbon nanocomposite material (e.g., using a filtration process or a centrifugation process).
Statement 5. A method according to any one of the preceding Statements, further comprising washing the silicon-carbon nanocomposite material (e.g., washing the silicon-carbon nanocomposite material with a solvent such as, for example, ethanol, which is desirable to avoid forming an oxide layer on the silicon nanoparticles (and to separate them from the filter medium more easily) and the washing step may be repeated).
Statement 6. A method according to any one of the preceding Statements, further comprising drying the silicon-carbon nanocomposite material (e.g., drying the clusters in a vacuum oven).
Statement 7. A method according to any one of the preceding Statements, further comprising lithiating the silicon-carbon nanocomposite material. The lithiation may be carried out before or after fabrication of an electrode.
Statement 8. A method according to any one of the preceding Statements, wherein the silicon oxide-coated silicon nanoparticles are sintered during the forming of clusters of silicon oxide-coated silicon nanoparticles.
Statement 9. A method according to any one of the preceding Statements, further comprising sintering the carbon-material-coated silicon oxide-coated silicon nanoparticles. Optionally, the sintering process is carried out in an atmosphere comprising hydrogen, which may increase the graphene content of the carbon containing layer.
Statement 10. A method according to any one of the preceding Statements, wherein the silicon nanoparticles are crystalline, polycrystalline, amorphous, or a combination thereof and/or have a longest dimension (e.g., a diameter) of 5 to 250 nm (e.g., 5 to 150 nm), including all nm ranges and values therebetween (e.g., 20-75 nm, including all 0.1 nm values and ranges therebetween).
Statement 11. A method according to any one of the preceding Statements, wherein the silicon nanoparticles are spherical, quasi-spherical, irregularly shaped, or a combination thereof. Other shapes are possible.
Statement 12. A method according to any one of the preceding Statements, wherein the forming comprises applying pressure (e.g., at pressures of 30 to 1000 MPa, including all MPa values and ranges therebetween) to the silicon oxide-coated silicon nanoparticles using a die set and a hydraulic press to form compacted clusters of silicon oxide-coated silicon nanoparticles and milling (e.g., ball milling, hammer milling, jet milling, roller milling, and the like) the compacted clusters of silicon oxide-coated silicon nanoparticles to form clusters of silicon oxide-coated silicon nanoparticles.
Statement 13. A method according to any one of the preceding Statements, wherein a conducting carbon material (e.g., carbon black, carbon nanotubes, or graphene such as, for example, graphene sheets, is added to the silicon oxide-coated silicon nanoparticles prior to forming clusters of the silicon oxide-coated silicon nanoparticles.
Statement 14. A method of any one according to Statements 12 or 13, wherein the compacted silicon oxide-coated silicon nanoparticles are sintered (e.g., at 600° C. in an inert atmosphere) after applying pressure to the silicon oxide-coated silicon nanoparticles and before milling the compacted silicon oxide-coated silicon nanoparticles. It is desirable that the sintering environment be inert at high temperatures to avoid further oxidation of the silicon oxide-coated silicon nanoparticles. However, at low temperatures it can be air. For example, the sintering time is 30 minutes to two hours, including all 0.1 minute values and ranges therebetween.
Statement 15. A method according to any one of the preceding Statements, wherein the forming of carbon-material-coated clusters of silicon oxide-coated silicon nanoparticles is carried out using chemical vapor deposition (e.g., using acetylene as a carbon precursor and, optionally, using hydrogen). In an example, after stopping the carbon precursor gas flow, the carbon-material-coated clusters of silicon oxide-coated silicon nanoparticles are maintained at or near the deposition temperature to further pack the carbon material (e.g., make the carbon material more graphitic) and, optionally, hydrogen is added during this process).
Statement 16. A method according to any one of the preceding Statements, further comprising the one or more additional carbon coating steps (e.g., as described herein).
Statement 17. A method for making a silicon-carbon nanocomposite material (e.g., a silicon-carbon nanocomposite material comprising a plurality of silicon@void@carbon clusters) comprising: providing silicon oxide (e.g., silicon dioxide)-coated nanoparticles (e.g., silicon nanoparticles with a continuous coating of silicon oxide) (e.g., forming silicon oxide (e.g., silicon dioxide)-coated nanoparticles by heating (e.g., thermally oxidizing) silicon nanoparticles in an oxidizing atmosphere (e.g., air, water, oxidizing gases such as, for example, ozone, nitrous oxides, and the like) having, for example, a silicon oxide thickness of 5 to 500 nm, including all nm ranges and values therebetween (e.g., 1-300 nm, less than 250 nm, or less than 150 nm)); forming carbon-material (e.g., carbon material such as, for example, graphene, graphene-like material, graphitic carbon material, or a combination thereof)-coated silicon oxide-coated silicon nanoparticles (e.g., by contacting the silicon oxide-coated silicon nanoparticles with a gas-phase carbon precursor such as, for example, acetylene) having, for example, a carbon material thickness of 0.3 to 20 nm, including all 0.1 nm values and ranges therebetween (e.g., 0.3 to 5 nm and 5-10 nm); and forming clusters of carbon-material-coated silicon oxide-coated silicon nanoparticles (e.g., by applying pressure to the carbon-material-coated silicon oxide-coated silicon nanoparticles (e.g., using a die set and hydraulic press, a tablet press, a stamp press, or a roller press, and the like) to form compacted (e.g., agglomerated) clusters of carbon-material-coated silicon oxide-coated silicon nanoparticles and milling (e.g., ball milling, hammer milling, jet milling, roller milling, and the like) the compacted clusters of carbon-material-coated silicon oxide-coated silicon nanoparticles to form clusters of carbon-coated silicon oxide-coated silicon nanoparticles); and removing all or substantially all (e.g., 80% or greater, 85% or greater, 90% or greater, and 95%, or greater) of the silicon oxide from the clusters of carbon-material-coated silicon oxide-coated silicon nanoparticles (e.g., by contacting the carbon-material-coated silicon oxide-coated silicon nanoparticles with an acid such as, for example, aqueous hydrofluoric acid) or a base such as, for example, an aqueous alkali metal hydroxide, such that the silicon-carbon nanocomposite material is formed.
Statement 18. A method according to Statement 17, further comprising isolating the silicon-carbon nanocomposite material (e.g., using a filtration process or a centrifugation process).
Statement 19. A method according to Statements 17 or 18, further comprising washing the silicon-carbon nanocomposite material (e.g., washing the silicon-carbon nanocomposite material with a solvent such as, for example, ethanol, which is desirable to avoid forming an oxide layer on the silicon nanoparticles and/or to separate them from the filter medium easier). The washing step may be repeated.
Statement 20. A method according any one of Statements 17-19, further comprising drying the silicon-carbon nanocomposite material (e.g., drying the clusters in a vacuum oven).
Statement 21. A method according any one of Statements 17-20, further comprising lithiating the silicon-carbon nanocomposite material. The lithiation may be carried out after formation of an anode material and/or anode.
Statement 22. A method according any one of Statements 17-21, wherein the carbon-material-coated silicon oxide-coated silicon nanoparticles are sintered during the forming of clusters of carbon-material-coated silicon oxide-coated silicon nanoparticles.
Statement 23. A method according any one of Statements 17-22, wherein a conducting carbon material (e.g., carbon black, carbon nanotubes, or graphene such as, for example, graphene sheets), is added to the carbon-material-coated silicon oxide-coated silicon nanoparticles prior to forming clusters of the silicon oxide-coated silicon nanoparticles.
Statement 24. A method according any one of Statements 17-23, wherein the silicon nanoparticles are crystalline, polycrystalline, amorphous, or a combination thereof and/or have a longest dimension (e.g., a diameter) of 5 to 250 nm, including all nm values and ranges therebetween (e.g., 5 to 150 nm or 20-75 nm).
Statement 25. A method according any one of Statements 17-24, wherein the silicon nanoparticles are spherical, quasi-spherical, irregularly shaped, or a combination thereof. Other shapes are possible.
Statement 26. A method according any one of Statements 14-19, wherein the forming comprises applying pressure (e.g., at pressures of 30 to 1000 MPa, including all MPa values and ranges therebetween) to the carbon-material-coated silicon oxide-coated silicon nanoparticles using a die set and a hydraulic press to form compacted clusters of carbon-material coated silicon oxide-coated silicon nanoparticles and milling (e.g., ball milling, hammer milling, jet milling, roller milling, and the like) the compacted clusters of carbon-material coated silicon oxide-coated silicon nanoparticles to form clusters of silicon oxide-coated silicon nanoparticles.
Statement 27. A method according to Statement 26, the carbon-material coated silicon oxide-coated silicon nanoparticles are sintered (e.g., at 600° C. in an inert atmosphere) after applying pressure to the carbon-material coated silicon oxide-coated silicon nanoparticles and before milling the compacted carbon-material coated silicon oxide-coated silicon nanoparticles. The sintering environment should be inert to avoid removal of carbon by oxidation. For example, the sintering time is 30 minutes to two hours, including all 0.1 minute values and ranges therebetween.
Statement 28. A method according any one of Statements 17-27, wherein the forming carbon-material-coated clusters of silicon oxide-coated silicon nanoparticles is carried out using chemical vapor deposition (e.g., using acetylene as a carbon precursor and, optionally, using hydrogen). In an example, after stopping the carbon precursor gas flow, the carbon-material-coated clusters of silicon oxide-coated silicon nanoparticles are maintained at or near the deposition temperature to further pack the carbon material (e.g., make the carbon material more graphitic) and, optionally, hydrogen in added during this process).
Statement 29. A method according any one of Statements 17-28, further comprising the one or more additional carbon coating steps (e.g., as described herein).
Statement 30. A method for making a silicon-carbon nanocomposite material (e.g., a silicon-carbon nanocomposite material comprising a plurality of silicon@void@carbon clusters) comprising: forming carbon-material (e.g., carbon material such as, for example, graphene, graphene-like material, graphitic carbon material, or a combination thereof)-coated silicon nanoparticles (e.g., by contacting the silicon nanoparticles with a gas-phase carbon precursor such as, for example, acetylene) having, for example, a carbon material thickness of 0.3 to 20 nm, including 0.1 nm values and ranges therebetween (e.g., 0.3 to 5 nm and 5-10 nm); and removing at least a portion of the silicon from the carbon-material-coated silicon nanoparticles (e.g., by contacting the carbon-material-coated silicon nanoparticles with an agent such as, for example, Group I metal hydroxides (e.g., lithium hydroxide, potassium hydroxide, and the like), that dissolves the silicon of the silicon nanoparticles without or substantially without removing the carbon material) such that a silicon-carbon nanocomposite material is formed.
Statement 31. A method according to Statement 30, wherein the silicon nanoparticles are crystalline, polycrystalline, amorphous, or a combination thereof and/or have a longest dimension (e.g., a diameter) of 5 to 250 nm, including all nm values and ranges therebetween (e.g., 5 to 150 nm or 20-50 nm).
Statement 32. A method according to Statements 30 or 31, wherein the silicon nanoparticles are spherical, quasi-spherical, irregularly shaped, or a combination thereof. Other shapes are possible.
Statement 33. A method according to any one of Statements 30-32, wherein the forming carbon-material-coated clusters of silicon oxide-coated silicon nanoparticles is carried out using chemical vapor deposition (e.g., using acetylene as a carbon precursor and, optionally, using hydrogen). In an example, after stopping the carbon precursor gas flow, the carbon-material-coated clusters of silicon oxide-coated silicon nanoparticles are maintained at or near the deposition temperature to further pack the carbon material (e.g., make the carbon material more graphitic) and, optionally, hydrogen in added during this process.
Statement 34. A method according to any one of Statements 30-33, wherein the carbon-material coated silicon oxide-coated silicon nanoparticles are sintered.
Statement 35. A method according to any one of Statements 30-34, further comprising the one or more additional carbon coating steps (e.g., as described herein).
Statement 36. A silicon-carbon nanocomposite material comprising: a silicon nanoparticle; a continuous carbon shell; and a void space within the carbon shell, wherein the silicon nanoparticle is encapsulated in the continuous carbon shell.
Statement 37. A silicon-carbon nanocomposite material according to Statement 36, wherein the silicon-carbon nanocomposite material comprises a plurality of particles (e.g., wherein the plurality of particles form a cluster of particles or a plurality of clusters of particles) and each particle comprises: a silicon nanoparticle; a continuous carbon shell; and a void space within the carbon shell, wherein the silicon nanoparticle is encapsulated in the continuous carbon shell.
Statement 38. A silicon-carbon nanocomposite material according to Statement 37, wherein the silicon-carbon nanocomposite material has at least 75% silicon by weight based on the total weight of the silicon-carbon nanocomposite material.
Statement 39. A silicon-carbon nanocomposite material according to Statement 36, wherein the silicon nanoparticles have a longest dimension (e.g., a diameter) of 5-250 nm, including all nm values and ranges therebetween (e.g., 5-150 nm or 20-50 nm).
Statement 40. A silicon-carbon nanocomposite material according to Statements 37 or 38, wherein the silicon nanoparticles have a longest dimension (e.g., a diameter) of 5-250 nm, including all nm values and ranges therebetween (e.g., 5-150 nm or 20-75 nm).
Statement 41. A silicon-carbon nanocomposite material according to any one of Statements 36-40, wherein the continuous carbon shell has a thickness of 0.3 to 20 nm, including all 0.1 nm values and ranges therebetween (e.g., 0.3 to 5 nm and 5-10 nm).
Statement 42. A silicon-carbon nanocomposite material according to any one of Statements 36-41, wherein the continuous carbon shell is not 100% amorphous.
Statement 43. A silicon-carbon nanocomposite material according to any one of Statements 36-42, wherein the continuous carbon shell is not defect-free graphene.
Statement 44. A silicon-carbon nanocomposite material according to any one of Statements 36-43, wherein the continuous carbon shell comprises carbon material that exhibits a Raman spectrum with a D(sp³ carbon)/G(sp² carbon) ratio of 0.7-2, including all 0.1 ratio values and ranges therebetween.
Statement 45. A silicon-carbon nanocomposite material according to Statement 44, wherein the continuous carbon shell comprises carbon material that exhibits a Raman spectrum that also exhibits an observable G′ peak (e.g., an observable G′ peak in the Raman spectrum).
Statement 46. A silicon-carbon nanocomposite material according to Statement 45, wherein the continuous carbon shell comprises carbon material that exhibits a Raman spectrum that also exhibits a G′/G ratio of 0.1-0.7.
Statement 47. A silicon-carbon material according to any one of Statements 36-46, wherein the volume ratio of void space to silicon nanoparticle volume ((void volume+silicon nanoparticle volume)/silicon volume) is 3-5, including all ranges and values therebetween (e.g., 3.8-4.2).
Statement 48. A silicon-carbon material according to any one of Statements 36-47, wherein the silicon-carbon material is made by a method of any one according to Statements 1-35.
Statement 49. An anode for an ion-conducting battery comprising a silicon nanocomposite material of any one according to Statements 36-47 or a silicon nanocomposite material made by a method of any one according to Statements 1-35.
Statement 50. An anode according to Statement 49, further comprising one or more binders (e.g., polymers (e.g., conductive polymers) such as, for example, PVDF, PAA, CMC, Alginate, polyethylene oxide (PEO), poly(vinyl alcohol) (PVA), polyaniline (PANT), poly (9,9-dioctyl-fluorene-co-fluorenone) (PFFO), poly(9,9-dioctylfluorene-co-fluorenone-co-methylbenzoic acid) (PFFOMB), polyamide-imide (PAI), lithium poly(acrylic acid) (PAALi), and sodium poly(acrylic acid) (PAANa), and the like and combinations thereof).
Statement 51. An anode according to Statements 49 or 50, further comprising one or more carbon additives (e.g., carbon nanotubes, carbon black, graphene (e.g., graphene sheets), and combinations thereof).
Statement 52. An anode according to any one of Statements 49-51, wherein the anode exhibits an anode capacity of at least 1,000 mAh/g for at least 1,000 cycles at a current of 3,500 mA/g or at least 2,000 mAh/g for at least 50 cycles or at least 250 cycles at a current of 400 mA/g.
Statement 53. An ion-conducting battery (e.g., a lithium ion battery) comprising a silicon nanocomposite material of any one according to Statements 36-47 or a silicon nanocomposite material made by a method of any one according to Statements 1-35 (e.g., comprising an anode of any one according to Statements 46-49 or a silicon nanocomposite material made by a method of any one according to Statements 1-35).
Statement 54. An ion-conducting battery according to Statement 53 wherein the battery further comprises one or more electrolyte and/or one or more current collector and/or one or more additional structural components (e.g., bipolar plates, external packaging, and electrical contacts/leads to connect wires, etc.).
Statement 55. An ion-conducting battery comprising a plurality of cells, each cell comprising one or more an anode of any one according to Statements 49-52, and optionally, one or more cathode(s), electrolyte(s), and current collector(s).
Statement 56. An ion-conducting battery according to Statement 55, wherein the battery comprises 1 to 500 cells, including all cell values and ranges therebetween.

The following examples are presented to illustrate the present disclosure. They are not intended to limiting in any matter.

### Example 1

This example provides a description of making, characterizing, and using silicon-carbon nanomaterials of the present disclosure.

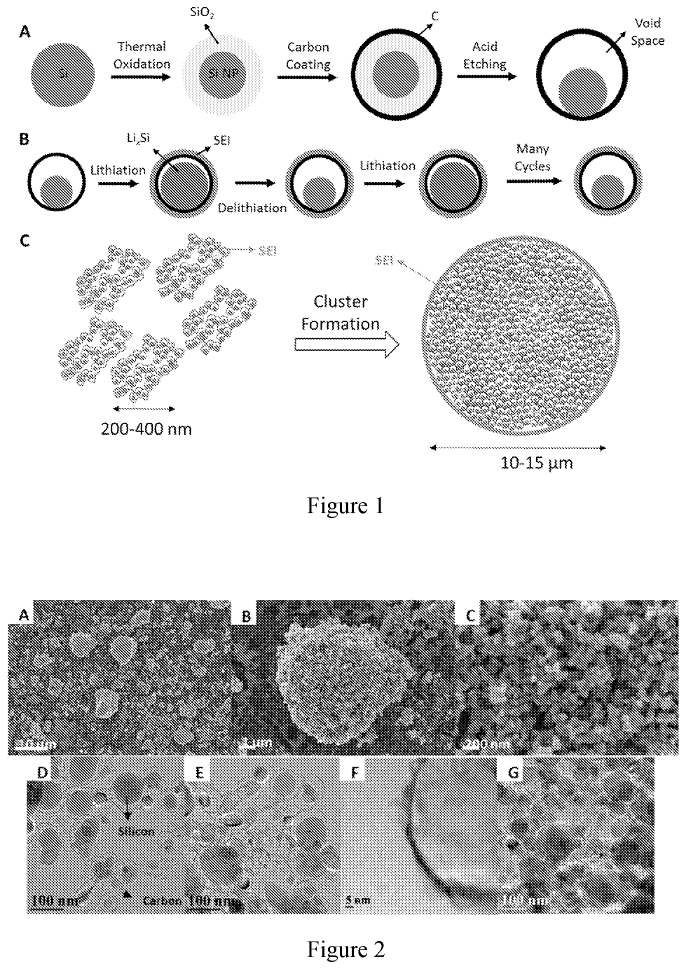

We have synthesized the silicon-carbon clusters by using ˜100 nm silicon nanoparticles purchased from Sigma Aldrich. As illustrated in FIG. 1.A, we thermally oxidized the nanoparticles in the air to not only make the silicon nanoparticles smaller, but also to provide a sacrificial layer that will eventually become void space to accommodate silicon volume expansion (FIG. 1.B). We then pressed the oxidized nanoparticles with a hydraulic press and ball milled them to form 5-15 μm clusters (FIG. 2.A-B). Each cluster includes individually oxidized silicon nanoparticles (FIG. 2.C). Later, we carbon-coated the oxidized nanoparticle by exposure to acetylene gas in a tube furnace at temperatures above 1000° C. to form graphene-like carbon. Because the clusters are porous, the carbon penetrated into the clusters and coated the individual nanoparticles. The silicon@oxide@carbon clusters were etched to remove the oxide layer and form silicon@void@carbon clusters with more than 85% silicon content. In order to examine the individual nanoparticle morphology, we performed the process without cluster formation. Images of those structures are provided in FIG. 2.D-E. Each silicon nanoparticle has a void space for volume expansion, which is relatively uniform for all the nanoparticles. The carbon layer protects the silicon nanoparticle from the electrolyte, while providing a conductive layer. FIG. 2.F shows that the carbon layer thickness is as thin as 5 nm. As presented in FIG. 2.G, the carbon shell survives compression to 950 MPa pressure and did not break. This result demonstrates that roll-pressing of electrode during manufacturing will not affect the anode material structure.

These processes are highly tunable. We can tune the oxide layer thickness by changing oxidation time and temperature. We can tune the carbon content by changing the coating time and acetylene flow rate. We can change the carbon type (degree of graphitization) by changing the furnace temperature. We can tune the size of clusters by changing the milling energy and time. Furthermore, these processes are highly scalable and very well-known in the chemical industry, unlike solution phase processes for silicon oxide (e.g., SiO₂) and carbon layer growth or nanowire-growth processes that have been published by others. The cost of implementing our processes is expected to be much lower than other methods such as nanowire growth for which a gold catalyst is required, or multi-step solution-phase growth of an organic shell followed by a separate carbonization step. FIG. 8 shows the galvanostatic cycling of the silicon-carbon anode material at different current densities.

### Example 2

This example provides a description of making, characterizing, and using silicon-carbon nanomaterials of the present disclosure.

Results for silicon-carbon nanocomposite for lithium-ion battery application.

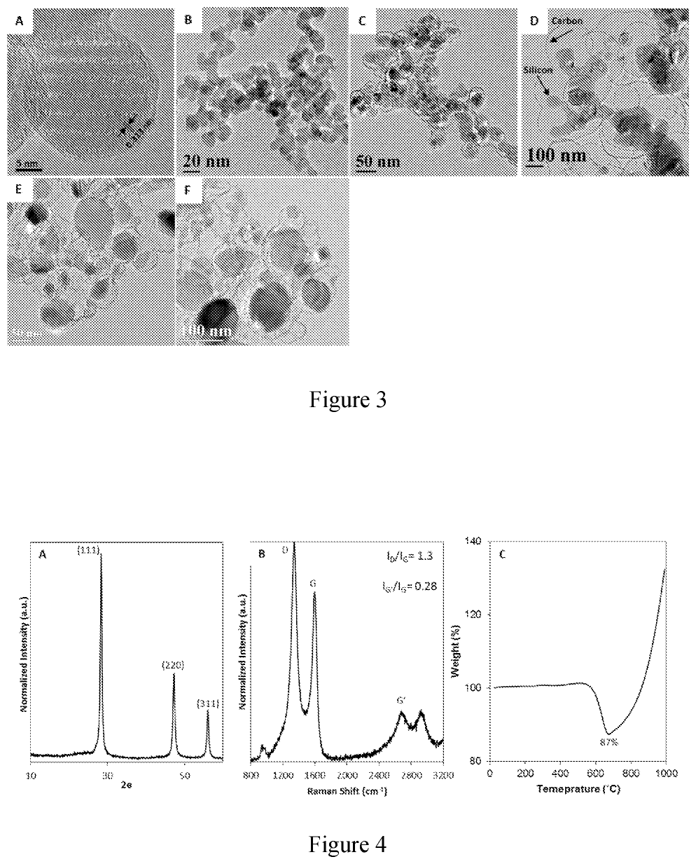

We prepared silicon nanoparticles in a laser pyrolysis reactor using silane gas as a precursor. The unique design of the reactor provides rapid heating and rapid cooling leading to the formation of 25-35 nm, oxide-free and hydrogen passivated silicon nanoparticles (FIGS. 3.A-B). To provide void space for silicon expansion, we grew a sacrificial silica layer on the surface of the nanoparticles by a modified Stöber method in an aqueous solution process. We tuned the void space by varying the oxide layer thickness. Then, we grew a carbon layer in a CVD process using acetylene gas as the carbon source. We tuned the carbon layer thickness (carbon content in the final material) by changing the CVD time. At this point, the silicon nanoparticles were coated with silica and covered with a conformal carbon layer. We used an acid etching process to remove the silica sacrificial layer. Because the silicon nanoparticles are aggregated in the production process, the final silicon-carbon material forms a composite type material (FIGS. 3.C-D). We prepared the same structure, by the same processes, using commercially available ˜100 nm silicon particles (FIGS. 3. E-F) in order to compare the performance of similar structures of different size in galvanostatic charge/discharge experiments.

FIG. 4 shows characterization of the obtained silicon-carbon nanocomposite. X-ray diffraction in FIG. 4.A demonstrates the presence of silicon (111), (220), and (311) peaks at ˜28°, 47°, and 56°, respectively. The absence of peaks associated with silicon carbide indicates that the carbon atoms do not chemically react with silicon or silica during the carbon-coating process, which is very important because silicon carbide does not have lithium-storage ability. The Raman spectrum in FIG. 4.B demonstrates that the carbon structure is similar to graphene rather than amorphous carbon. Presence of the G′ band at ˜2700 cm⁻¹ demonstrates that the carbon layer is not amorphous. However, the I_{D}/I_{G} ratio is more than one demonstrating that the graphitic carbon structure is significantly distorted and defective. This is because we perform the carbon-coating process rapidly (<1 min) to keep the carbon content below 20%. Therefore, the graphene layers did not merge and stack to create 100% graphitic carbon. If we increase the carbon-coating time, more graphene layers form, merge and stack, which decreases the distortion and brings the I_{D}/I_{G} ratio below one. Son et. al. experimentally demonstrated the effect of graphene growth time on the degree of graphitization. They observed an I_{D}/I_{G} ratio less than one when the carbon-coating process was on the order of several minutes. FIG. 4.C shows thermogravimetric analysis (TGA) of the silicon-carbon nanocomposite using air as a carrier gas. The 13% weight loss measured by the system shows the carbon content. Afterward, the silicon nanoparticles oxidize, leading to weight gain.

We fabricated electrodes on a thin copper foil using a slurry method. The slurry was prepared by mixing the active material, CNT, and PVDF in ratios of 65:20:15. The C-rates (charge/discharge rates) are calculated with respect to the theoretical capacity of silicon (1C=4200 mAh/g) and mass of the active material. The C-rate is a measure of the rate at which a battery is charged or discharged relative to its maximum capacity. For example, a C-rate of C/10 means that the necessary current is applied or drained from the battery to charge or discharge it completely (to its theoretical capacity) in 10 hours. The electrolyte consists of 1.0 M Lithium hexafluorophosphate (LiPF₆) in 1:1 w/w ethylene carbonate/diethyl carbonate. 10 vol % fluoroethylene carbonate (FEC) and 1 vol % vinylene carbonate (VC) were added to promote SEI stabilization.

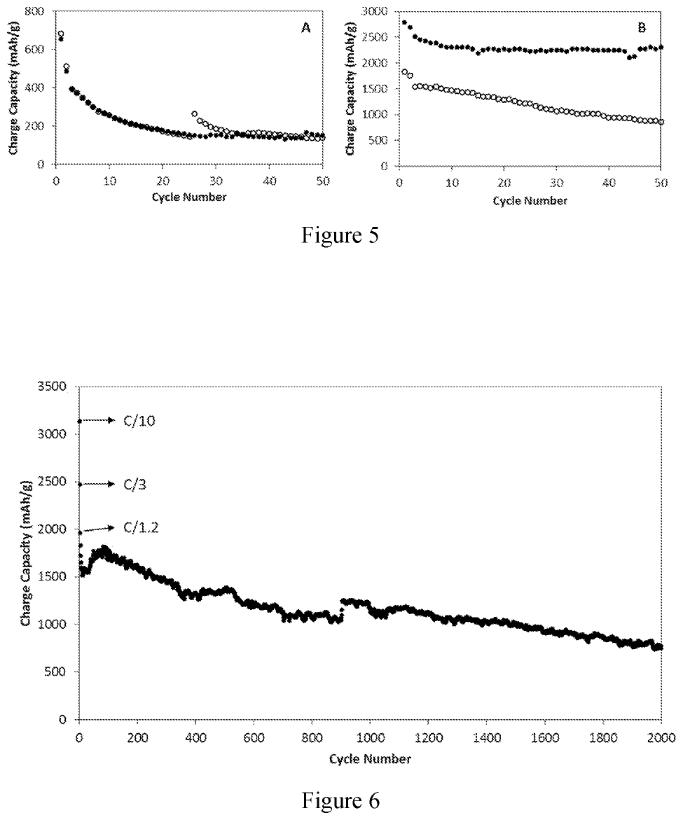

Before testing the prepared nanocomposite structure, we performed slow galvanostatic cycling of the carbon-coated 35 and 100 nm nanoparticles without any void space. The results in FIG. 5.A show that capacity drops very fast due to continuous SEI growth and consumption of the electrolyte. On the other hand, providing a void space for silicon nanoparticles significantly improves the anode material performance. As presented in FIG. 5.B, the nanocomposite synthesized with 35 nm silicon nanoparticles stabilizes at ˜2300 mAh/g after 50 cycles at C/10. However, the nanocomposite synthesized with 100 nm silicon nanoparticles stabilizes at ˜900 mAh/g after 50 cycles at C/10. Therefore, the galvanostatic data shows that the 35 nm particles provide higher performance because of their shorter ionic and transport distances.

We also performed fast galvanostatic cycling of the 35 nm silicon-carbon nanocomposite with void space. As presented in FIG. 6, the capacity reached 1000 mAh/g after 1500 cycles at C/1.2 or 0.62 mA/cm² current density. We believe the fluctuations in the capacity relate to the SEI layer stability. Although the FEC additive in the electrolyte limits cracking of the SEI, high current over a large number of cycles might still crack the SEI leading to the capacity loss. This result demonstrates our successful effort to eliminate the detrimental effects associated with silicon and the high potential of the silicon-based anode material we developed.

Although the present disclosure has been described with respect to one or more particular embodiments and/or examples, it will be understood that other embodiments and/or examples of the present disclosure may be made without departing from the scope of the present disclosure.

1. A method for making a silicon-carbon nanocomposite material comprising:
providing silicon oxide-coated silicon nanoparticles having a silicon oxide thickness of 5 to 500 nm;
forming clusters of silicon oxide-coated silicon nanoparticles;
forming carbon-material-coated clusters of silicon oxide-coated silicon nanoparticles having a carbon material thickness of 0.3 to 20 nm; and
removing all or substantially all of the silicon oxide from the carbon-material-coated clusters of silicon oxide-coated silicon nanoparticles, such that the silicon-carbon nanocomposite material is formed.

2. The method of claim 1, further comprising isolating the silicon-carbon nanocomposite material.

3. The method of claim 1, further comprising washing the silicon-carbon nanocomposite material.

4. The method of claim 1, further comprising drying the silicon-carbon nanocomposite material.

5. The method of claim 1, further comprising lithiating the silicon-carbon nanocomposite material, wherein the lithiating is carried out before or after fabrication of an electrode.

6. The method of claim 1, wherein the silicon oxide-coated silicon nanoparticles are sintered during the forming of clusters of silicon oxide-coated silicon nanoparticles.

7. The method of claim 1, further comprising sintering the carbon-material-coated silicon oxide-coated silicon nanoparticles, wherein the sintering process is optionally carried out in atmosphere comprising hydrogen.

8. The method of claim 1, wherein the silicon nanoparticles of the silicon-carbon nanocomposite material are crystalline, polycrystalline, amorphous, or a combination thereof and/or have a longest dimension of 5 to 150 nm.

9. The method of claim 1, wherein the silicon nanoparticles are spherical, quasi-spherical, irregularly shaped, or a combination thereof.

10. The method of claim 1, wherein the forming comprises applying pressure to the silicon oxide-coated silicon nanoparticles using a die set and a hydraulic press to form compacted clusters of silicon oxide-coated silicon nanoparticles and milling the compacted clusters of silicon oxide-coated silicon nanoparticles to form clusters of silicon oxide-coated silicon nanoparticles.

11. The method of claim 1, wherein a conducting carbon material is added to the silicon oxide-coated silicon nanoparticles prior to forming clusters of the silicon oxide-coated silicon nanoparticles.

12. The method of claim 9, wherein the compacted silicon oxide-coated silicon nanoparticles are sintered after applying pressure to the silicon oxide-coated silicon nanoparticles and before milling the compacted silicon oxide-coated silicon nanoparticles.

13. The method of claim 1, wherein the forming carbon-material-coated clusters of silicon oxide-coated silicon nanoparticles is carried out using chemical vapor deposition.

14. The method of claim 1, further comprising the one or more additional carbon coating steps.

15. A method for making a silicon-carbon nanocomposite material comprising:
providing silicon oxide-coated silicon nanoparticles;
forming carbon-material-coated silicon oxide-coated silicon nanoparticles, wherein a carbon material thickness of 0.3 to 20 nm; and
forming clusters of carbon-material-coated silicon oxide-coated silicon nanoparticles; and
removing all or substantially all of the silicon oxide from the clusters of carbon-material-coated silicon oxide-coated silicon nanoparticles, such that the silicon-carbon nanocomposite material is formed.

16. The method of claim 15, further comprising isolating the silicon-carbon nanocomposite material.

17. The method of claim 15, further comprising washing the silicon-carbon nanocomposite material.

18. The method of claim 15, further comprising drying the silicon-carbon nanocomposite material.

19. The method of claim 15, further comprising lithiating the silicon-carbon nanocomposite material.

20. The method of claim 15, wherein the carbon-material-coated silicon oxide-coated silicon nanoparticles are sintered during the forming of clusters of carbon-material-coated silicon oxide-coated silicon nanoparticles.

21. The method of claim 15, wherein a conducting carbon material is added to the carbon-material-coated silicon oxide-coated silicon nanoparticles prior to forming clusters of the silicon oxide-coated silicon nanoparticles.

22. The method of claim 15, wherein the silicon nanoparticles of the silicon-carbon nanocomposite material are crystalline, polycrystalline, amorphous, or a combination thereof and/or have a longest dimension of 5 to 150 nm.

23. The method of claim 15, wherein the silicon nanoparticles are spherical, quasi-spherical, irregularly shaped, or a combination thereof.

24. The method of claim 15, wherein the forming comprises applying pressure to the carbon-material-coated silicon oxide-coated silicon nanoparticles using a die set and a hydraulic press to form compacted clusters of carbon-material coated silicon oxide-coated silicon nanoparticles and milling the compacted clusters of carbon-material coated silicon oxide-coated silicon nanoparticles to form clusters of silicon oxide-coated silicon nanoparticles.

25. The method of claim 24, the carbon-material coated silicon oxide-coated silicon nanoparticles are sintered after applying pressure to the carbon-material coated silicon oxide-coated silicon nanoparticles and before milling the compacted carbon-material coated silicon oxide-coated silicon nanoparticles.

26. The method of claim 15, wherein the forming carbon-material-coated clusters of silicon oxide-coated silicon nanoparticles is carried out using chemical vapor deposition.

27. The method of claim 15, further comprising the one or more additional carbon coating steps.

28. A method for making a silicon-carbon nanocomposite material comprising:
forming carbon-material-coated silicon nanoparticles; and
removing at least a portion of the silicon from the carbon-material-coated silicon nanoparticles, such that a silicon-carbon nanocomposite material is formed.

29. The method of claim 28, wherein the silicon nanoparticles of the silicon-carbon nanocomposite are crystalline, polycrystalline, amorphous, or a combination thereof and/or have a longest dimension of 5 to 250 nm.

30. The method of claim 28, wherein the silicon nanoparticles are spherical, quasi-spherical, irregularly shaped, or a combination thereof.

31. The method of claim 28, wherein the forming carbon-material-coated clusters of silicon oxide-coated silicon nanoparticles is carried out using chemical vapor deposition.

32. The method of claim 28, wherein the carbon-material coated silicon oxide-coated silicon nanoparticles are sintered.

33. The method of claim 28, further comprising the one or more additional carbon coating steps.

34. A silicon-carbon nanocomposite material comprising:
a silicon nanoparticle;
a continuous carbon shell; and
a void space within the carbon shell,
wherein the silicon nanoparticle is encapsulated in the continuous carbon shell.

35. The silicon-carbon nanocomposite material of claim 34, wherein the silicon-carbon nanocomposite material comprises a plurality of particles and each particle comprises:
a silicon nanoparticle;
a continuous carbon shell; and
a void space within the carbon shell,
wherein the silicon nanoparticle is encapsulated in the continuous carbon shell.

36. The silicon-carbon nanocomposite material of claim 35, wherein the silicon-carbon nanocomposite material has at least 75% silicon by weight based on the total weight of the silicon-carbon nanocomposite material.

37. The silicon-carbon nanocomposite material of claim 34, wherein the silicon nanoparticles of the silicon-carbon nanocomposite have a longest dimension of 5-150 nm, including all nm values and ranges therebetween.

38. The silicon-carbon nanocomposite material of claim 35, wherein the silicon nanoparticles have a longest dimension of 5-150 nm, including all nm values and ranges therebetween.

39. The silicon-carbon nanocomposite material of claim 34, wherein the continuous carbon shell has a thickness of 0.3 to 20 nm.

40. The silicon-carbon nanocomposite material of claim 34, wherein the continuous carbon shell is not 100% amorphous.

41. The silicon-carbon nanocomposite material of claim 34, wherein the continuous carbon shell is not defect-free graphene.

42. The silicon-carbon nanocomposite material of claim 34, wherein the continuous carbon shell comprises carbon material that exhibits a Raman spectrum with a D(sp³ carbon)/G(sp² carbon) ratio of 0.7-2.

43. The silicon-carbon nanocomposite material of claim 42, wherein the continuous carbon shell comprises carbon material that exhibits a Raman spectrum that also exhibits an observable G′ peak.

44. The silicon-carbon nanocomposite material of claim 43, wherein the continuous carbon shell comprises carbon material that exhibits a Raman spectrum that also exhibits a G′/G ratio of 0.1-0.7.

45. The silicon-carbon material of claim 34, wherein the volume ratio of void space to silicon nanoparticle volume ((void volume+silicon nanoparticle volume)/silicon volume) is 3-5.

46. An anode for an ion-conducting battery comprising a silicon nanocomposite material of claim 34.

47. The anode of claim 46, further comprising one or more binders.

48. The anode of claim 46, further comprising one or more carbon additives.

49. The anode of claim 46, wherein the anode exhibits an anode capacity of at least 1,000 mAh/g for at least 1,000 cycles at a current of 3,500 mA/g or at least 2,000 mAh/g for at least 50 cycles or at least 250 cycles at a current of 400 mA/g.

50. An ion-conducting battery comprising a silicon nanocomposite material of claim 34.

51. The ion-conducting battery of claim 50, wherein the battery further comprises one or more electrolyte and/or one or more current collector and/or one or more additional structural components.

52. A ion-conducting battery comprising a plurality of cells, each cell comprising one or more an anode of claim 46, and optionally, one or more cathode(s), electrolyte(s), and current collector(s).

53. The ion-conducting battery of claim 52, wherein the battery comprises 1 to 500 cells, including all cell values and ranges therebetween.
